(19) United States
(12) Patent Application Publication
(10) Pub. No.: US 2023/0078131 A1
(43) Pub. Date: Mar. 16, 2023

(54) DISPLAY DEVICE AND MANUFACTURING METHOD THEREOF

(71) Applicant: SeeYa Optronics, Ltd., Shanghai (CN)

(72) Inventor: Zhongshou Huang, Shanghai (CN)

(73) Assignee: SeeYa Optronics, Ltd., Shanghai (CN)

(21) Appl. No.: 17/944,890

(22) Filed: Sep. 14, 2022

(30) Foreign Application Priority Data
Sep. 16, 2021 (CN) 202111087167.2

(51) Int. Cl. H01L 51/52; H01L 51/56; G06F 1/16

(52) U.S. Cl. CPC H01L 51/5237; H01L 51/529; H01L 51/5275; H01L 51/56; G06F 1/163; H01L 27/3244

(57) ABSTRACT

A display device includes a barrel-shaped container filled with a liquid, an optical lens and an electronic display screen. The liquid is transparent and thermally conductive, the optical lens is mounted at one end of the barrel-shaped container, one surface of the optical lens is in contact with the liquid, and the electronic display screen includes a light emitting area and a transparent protection layer. The electronic display screen is configured at the other end of the barrel-shaped container, and the transparent protection layer thereof is in contact with the liquid. The optical lens has an optical axis that perpendicularly passes through the center of the light emitting area of the electronic display screen.

### CROSS-REFERENCE TO RELATED APPLICATION

This application claims priority to Chinese Patent Application No. 202111087167.2 filed Sep. 16, 2021, the disclosure of which is incorporated herein by reference in its entirety.

### TECHNICAL FIELD

The present disclosure relates to the field of display technology, and in particular to a display device and a manufacturing method thereof.

### BACKGROUND

Organic light emitting diodes (OLEDs) are considered to be the most promising new generation display technology because of their excellent characteristics such as self-luminescence, low energy consumption, wide viewing angle, rich color, rapid response and applicability for preparation of flexible display screen. As a new human-computer interaction mode in the field of intelligent wearing, the intelligent wearing provides exclusive, personalized services for consumers through intelligent apparatuses being worn on a human body. With the development of mobile internet technology and the maturity of core hardware technologies of wearable apparatuses, such as low-power chips and flexible circuit boards, some wearable apparatuses have gradually developed from conceptualization to commercialization.

Among those wearable apparatuses, augmented reality (AR) glasses and virtual reality (VR) glasses are relatively common intelligent wearable apparatuses currently. In the practical application of AR glasses and VR glasses, in one aspect, the device is required to be small in size, light in weight and compact in package in order to be portable. However, in another aspect, people unremittingly pursue graphic information with high brightness, high precision and rich color, three-dimensional image, and video image with a high refresh rate, all of which cause increase of power consumption per unit volume, and consequently the heat emitting issue becomes more serious. The heat generated by the system cannot be rapidly dissipated outward, and is apt to accumulate on the skin surface of the user. Since the skin surface is in direct contact with the apparatus, the user experience is adversely affected. From the user's feeling, a hot temperature felt by a hand is about 50 degrees Celsius. However, an apparatus worn on a person's face or head may cause the user to feel extremely discomfort if its temperature is near or slightly over 40 degrees Celsius. In extreme working environments, such as outdoor applications in summer, the heat emitting issue may cause rapid declination of the performance of organic light emitting film of an OLED display screen, system crash, and even burn of temperature-sensitive parts.

Currently, the issue of heat dissipation difficulty is common for intelligent wearable apparatuses, and becomes the bottleneck of product use. In addition, the heat dissipation will be getting more and more serious with the improvement of high integration and image resolution. Accordingly, a technical issue to be addressed by the person skilled in the art urgently is that the existing intelligent wearable apparatuses can not dissipate heat in time.

### SUMMARY

The present disclosure relates to a display device capable of dissipating heat rapidly. The display device includes a thermally conductive housing, an optical lens, a micro-display screen and a liquid. The optical lens, the micro-display screen and the liquid are packaged in the thermally conductive housing. The liquid is transparent and thermally conductive and mixed with a dispersant and nanoparticles, and lights emitted from the micro-display screen reach the optical lens via the thermally conductive liquid. In some examples, the thermally conductive liquid is embodied as a mixed solution of deionized water and ethylene glycol or is embodied as a silicone oil. In a particular embodiment, each of the nanoparticles is less than 100 nanometer (nm) in any dimension for further enhancing the thermally conductive property. These nanoparticles may be made of a metal such as gold, silver, or aluminum, or may be made of a metal oxide such as titanium oxide.

In some examples, the display device may include an aperture that also has the thermally conductive property, which aperture is embodied as a conic-shaped funnel structure to define a maximum divergence angle of lights and improve uniformity of the edge of the output beam. In a particular embodiment, the aperture and the thermally conductive housing may be made of a same metal material, and a black plating layer or a layer of low reflection film formed by anodizing or the like is provided on each light incident surface to reduce adverse effects of light reflection on the output image. In a particular embodiment, an inner sidewall of the aperture is a wetting surface, and the surface is provided with multiple groove structures or is roughened. In this way, not only air bubbles can be prevented from adhering, but also the contact area between the aperture and the thermally conductive liquid can be increased, thereby improving the heat exchange efficiency between the aperture and the thermally conductive liquid.

The present disclosure further provides, in a process of manufacturing the high-efficient heat-dissipating display device according to the present disclosure, a method of filling a thermally conductive liquid into a container and a packaging method, such as preforming an injection hole and an overflow hole in a container wall, and optimizing measures such as an ambient temperature under which the injecting and packaging are performed is higher than a skin temperature of a human body. These methods of filling the thermally conductive liquid and packaging are intended to ensure that leakage of the thermally conductive liquid does not occur and no bubbles and voids are generated in the container during later use, especially when the ambient temperature changes substantially.

### BRIEF DESCRIPTION OF DRAWINGS

The drawings herein is incorporated into the specification and forms part of this specification, shows an embodiment conforming to the present disclosure, and is used together with the specification to explain the principles of the present disclosure. Apparently, the drawings in the following description is only some embodiments of the present disclosure, and for those having ordinary skill in the art, other drawings can be obtained from these drawings without creative efforts.

FIG. 1 shows a side view of a display device according to a first embodiment of the present disclosure;

FIG. 2 shows a top view of the display device according to the first embodiment of the present disclosure;

FIG. 3 shows a side view of a display device according to another embodiment of the present disclosure;

FIG. 4 illustrates structures corresponding to a step 2 in a first manufacturing method of the display device according to the first embodiment of the present disclosure;

FIG. 5 illustrates structures corresponding to a step 3 in the first manufacturing method of the display device according to the first embodiment of the present disclosure;

FIG. 6 illustrates structures corresponding to a step 4 in the first manufacturing method of the display device according to the first embodiment of the present disclosure;

FIG. 7 shows a side view of a display device according to a second embodiment of the present disclosure;

FIG. 8 shows a top view of the display device according to the second embodiment of the present disclosure; and

FIG. 9 is a structural diagram of AR glasses according to an embodiment of the present disclosure.

### DETAILED DESCRIPTION

Hereinafter exemplary embodiments are further described in detail in conjunction with the drawings. However, exemplary embodiments may be implemented in many forms and should not be construed as being limited to the embodiments set forth herein. Rather, providing these embodiments/implementations enables the present disclosure to be comprehensive and complete, and fully communicate the concept of the exemplary embodiments/implementations to those skilled in the art. The same reference numeral in the figure denotes the same or similar structure, therefore, the descriptions thereof will not be repeated.

### First Embodiment

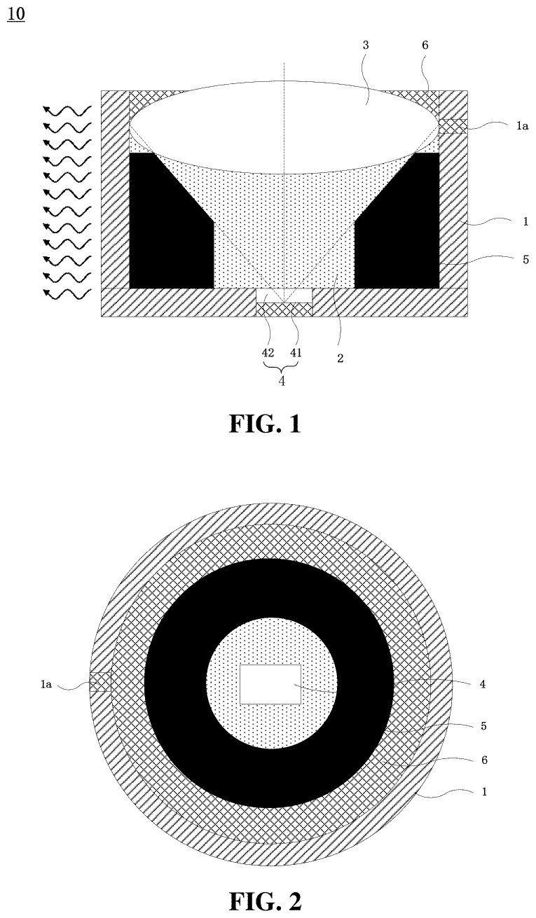

Referring to FIGS. 1 and 2, which are structural diagrams of a display device according to a first embodiment of the present disclosure. As shown in FIGS. 1 and 2, the display device 10 includes: a barrel-shaped container 1 filled with a liquid 2, liquid 2, an optical lens 3 and an electronic display screen 4. The liquid 2 is transparent and thermally conductive, the liquid 2 is mixed with a dispersant and nanoparticles, and the liquid 2 is filled in the barrel-shaped container 1. The optical lens 3 is mounted at one end of the barrel-shaped container 1 that one surface of the optical lens 3 is in contact with the liquid 2. The electronic display screen 4 includes a light emitting area 41 covered by a transparent protection layer 42. Specifically, the electronic display screen 4 is mounted at the other end of the barrel-shaped container 1, and the transparent protection layer 42 is in contact with the liquid 2. The optical lens 3 includes an optical axis that passes through the center of the light emitting area 41.

Specifically, the barrel-shaped container 1 is made of metal, ceramic, plastic or other thermally conductive materials, and the thermal conductivity of each of the metal, ceramic, plastic and other thermally conductive materials is required to be higher than the thermal conductivity of the liquid 2. In this way, the liquid 2 may conduct heat to the barrel-shaped container 1. In this embodiment, the barrel-shaped container 1 is a cylindrical container (i.e., a circular cylinder). Referring to FIGS. 1 and 2, the barrel-shaped container 1 includes a circular bottom plate and an annular side plate arranged to surround the circumference of the circular bottom plate, the annular side plate is perpendicular to the circular bottom plate, and the circular bottom plate and the annular side plate are integrally formed. In one embodiment. The circular bottom plate has a thickness greater than the thickness of the annular side plate, i.e., the thickness of a sidewall of the barrel-shaped container 1 is less than the thickness of its bottom housing. Thus, when the deformation occurs in the barrel-shaped container 1 due to thermal expansion and cold contraction, only the sidewall (i.e., the annular side plate) is deformed, and the container bottom (i.e., the circular bottom plate) is not deformed generally.

The liquid 2 is required to have a good thermally conductive performance and a high transparency to visible light. The thermal motion of the liquid molecules of the liquid 2 will be accelerated after the liquid 2 is heated, and the thermally conductive ability of the liquid 2 is far better than that of other media such as gas and plastic. Therefore, the liquid 2 is sealed in the barrel-shaped container 1, which enables the heat inside the container to be rapidly transferred to the housing of the barrel-shaped container 1, and then emitted to the ambient air to realize rapid heat dissipation.

In this embodiment, the liquid 2 further includes a mixed solution with deionized water and ethylene glycol. Specifically, the ethylene glycol has anti-freezing and anti-corrosion effects, and the volume ratio of the ethylene glycol in the mixed liquid is generally within a range from 20% to 40%. In a case where a mixed solution with deionized water and ethylene glycol is used as the liquid 2, the liquid 2 will not condense even in minus30 degrees Celsius (° C.) outdoors. In another embodiment, the main component of the liquid 2 is a silicone oil. The silicone oil has a thermal conductivity of 2 W/mK or higher, a freezing point as low as minus 50° C. , and a gasification point above 100° C. The silicone oil more suitably serves as the liquid 2 of the display device 10 than pure water having a thermal conductivity of about 0.6 W/mK.

In other embodiments, the liquid 2 may also be mixed with a proportion of dispersant and nanoparticles to further improve thermal conductivity and visible light transmittance. Specifically, each of the nanoparticles is less than 100 nanometer (nm) in any dimension. The nanoparticles include the nanorods (rod-shaped nanoparticles) that a ratio between an average diameter of the nanorods and an average length of the nanorods is less than 0.75. The nanorods are also referred to as nanowires, and have a length being less than 100 nm. The nanoparticles are made of a metal or metal oxide, the metal may be selected from gold, silver, copper or aluminum, and the metal oxide may be selected from titanium dioxide, aluminum oxide or copper oxide. The dispersant, such as citrate, will negatively charge the surface of the nanostructures in solution, thereby allowing the nanoparticles to repel each other without aggregating into larger particles and allowing visible lights having a wavelength ranging from 400 nm to 760 nm to pass through the liquid 2. The liquid 2 uniformly mixed with nanoparticles has a higher thermal conductivity (10 times or more) than the liquid 2 not mixed with nanostructures, and a visible light transmittance reaching 95% or more.

Still referring to FIG. 1, the display device 10 further includes an aperture structure 5. The aperture structure 5 is disposed in the liquid 2 and between the optical lens 3 and the electronic display screen 4, in a manner that the optical axis of the optical lens 3 passes through a center of the aperture structure 5. The aperture structure 5 is provided with an aperture (the reference numeral of the aperture is not shown in the figure) at a central position thereof, the aperture structure 5 includes a conic-shaped funnel structure with its larger exit being closest to the optical lens 3 and its smaller exit being closest to the electronic display screen 4. The aperture structure 5 includes a conic-shaped hole portion and a cylindrical hole portion communicating with each other, the diameter of the aperture gradually decreases in the conic-shaped hole portion till reaching the cylindrical hole portion, and remains at a minimum value over the cylindrical hole portion. A hole wall of the conic-shaped hole portion is a slope which is a part of a conic-shaped surface, and the conic-shaped surface has an apex corresponding to a central position of the light emitting area of the electronic display screen 4, and the center of the aperture is required to coincide with the optical axis of the optical lens 3. The aperture structure 5 may be utilized to define a maximum divergence angle of light beams emitted from the electronic display screen 4 and reaching the optical lens 3 via the liquid 2. Further, since the aperture structure 5 is embodied as the conic-shaped funnel structure, uniformity of the edge of the output beam may be improved, and reflection of lights at the end face of the aperture structure 5 may be reduced.

Still referring to FIG. 1, the aperture structure 5 has one end abutting on the bottom wall of the barrel-shaped container 1, the other end in contact with the optical lens 3, and an outer side face of the aperture structure 5 is in contact with an inner sidewall of the barrel-shaped container 1. In this way, the aperture structure 5 not only functions to restrict the maximum angle of the output light, but also functions to support and fix the optical lens 3 so as to ensure that the distance from the center of the optical lens 3 to the center of the light emitting area of the electronic display screen 4 is substantially equal to the focal length of the optical lens 3. In addition, the aperture structure 5 is made of a material that is opaque to light and has a good thermal conductivity, so that the heat in the liquid 2 may be transferred to the barrel-shaped container 1 through thermal conduction that is in direct contact with the barrel-shaped container 1.

In this embodiment, the aperture structure 5 is made of a metal material, or a non-metal material such as a resin or rubber doped with carbon powder. For example, the non-metal material may include a black conductive rubber or a black conductive resin. In one embodiment, the aperture structure 5 is made of metallic copper or metallic aluminum, so that the aperture structure 5 is ensured to have a high thermal conductivity.

In this embodiment, the fuel structure of the aperture structure 5 has a smooth inner sidewall, and the inner sidewall of the fuel structure has a wetting surface for the liquid 2. When liquid 2 is injected into the aperture structure 5, the liquid 2 is in close contact with the inner sidewall of the aperture structure 5, or in a wetting state in which the contact angle is less than 90 degrees. In a case where the inner sidewall is a wetting surface for the liquid 2, the liquid 2 fills all the gaps and fine potholes, and expels bubbles which may adhere to these places.

In order to further increase the heat exchange efficiency between the aperture structure 5 and the liquid 2, the inner sidewall of the aperture structure 5 may further be processed to increase the contact area between the aperture structure 5 and the liquid 2. Referring to FIG. 3, which shows a side view of a display device according to another embodiment of the present disclosure. As shown in FIG. 3, in another embodiment, an inner sidewall of the funnel structure of the aperture structure 5 is provided with multiple grooves arranged approximately at an equal interval, the depth of the grooves and the interval between grooves are configured to satisfy that the equivalent surface roughness is greater than 1.25. Surface roughness is defined as the ratio of an actual area to a projected area of a solid surface, generally greater than 1. For example, if the depth of a groove structure is equal to 1 mm, the total length of sidewalls of one groove structure is equal to 2 mm, and if the periodicity of one groove structure is equal to 4 mm, then the roughness is equal to 1.5. In order to improve the thermal conductivity efficiency, the equivalent surface roughness of this groove structure is set to be equal to or greater than 1.25 in this embodiment. In another embodiment of the present disclosure, an inner sidewall surface of the aperture structure 5 is roughened to have multiple dimples formed thereon which are arranged periodically or randomly so that the roughness of the inner sidewall surface configured to be equal to or greater than 1.25. The experiments show that the heat exchange efficiency between the aperture structure 5 and the liquid 2 may be effectively improved by roughening the inner sidewall of the aperture structure 5 or forming multiple groove structures on the inner sidewall of the aperture structure 5. In both embodiments, the inner sidewall of the aperture structure 5 is required to be a wetting surface for the liquid 2 to achieve possibility of increasing the wettability by roughness. Conversely, if the surface of the inner sidewall of the aperture structure 5 has a hydrophobic property, or an oil-repellent property (if the liquid 2 is oily) for the liquid 2, the roughness of the surface will reduce the wettability or hinder the close contact between the surface and the liquid 2 instead.

Still referring to FIG. 1, the electronic display screen 4 is configured to output an optical image, and includes a light emitting area 41 and a transparent protection layer 42. The transparent protection layer 42 covers the light emitting area 41 and is in direct contact with the liquid 2. The liquid 2 and the aperture structure 5 are both in direct contact with part of the inner wall of the barrel-shaped container 1, and the thermally conductive coefficients of the barrel-shaped container 1 and the aperture structure 5 are both higher than the thermally conductive coefficient of the liquid 2. In such way, the heat emitted by the electronic display screen 4 may be rapidly transmitted to the barrel-shaped container 1 and the aperture structure 5 through the liquid 2 filled in the barrel-shaped container 1, and is finally dissipated to the external environment. The area dissipating heat outwards as indicated by the arrows is mainly the sidewall of the barrel-shaped container 1.

In one embodiment, the electronic display screen 4 is a waterproof component and may be in direct contact with the liquid 2. The transparent protection layer 42 in the electronic display screen 4 may be a transparent protective film layer formed directly on the light emitting area 41, or may be a transparent cover plate disposed opposite to the light emitting area 41 and fixedly connected to the light emitting area 41.

In this embodiment, the electronic display screen 4 is embedded in an opening at the bottom of the barrel-shaped container 1, and the bottom of the electronic display screen 4 (i.e., a side facing away from the optical lens 3) is exposed outside, and signal wires and control wires of the electronic display screen 4 are directly led out from the bottom of the electronic display screen 4. In order to ensure that the transparent protection layer 42 of the electronic display screen 4 (i.e., a side facing the optical lens 3) is in sufficient contact with the liquid 2, the surface of the transparent protection layer 42 is required to be flush with or higher than an inner surface of the bottom of the barrel-shaped container 1.

In other embodiments, the electronic display screen 4 is directly fixed to the bottom of the barrel-shaped container 1, and the electronic display screen 4 is immersed in the liquid 2. For this purpose, the barrel-shaped container 1 is required be provided with a wire through hole, and the signal wires and control wires of the electronic display screen 4 are led out through the wire through hole provided in the barrel-shaped container 1.

In this embodiment, the size of the electronic display screen 4 is required to be smaller than the minimum hole diameter being the aperture structure 5 to ensure the integrity of the image display. The optical axis of the optical lens 3 perpendicularly passes through the center of the light emitting area 41 of the electronic display screen 4. In one embodiment, the centers of the electronic display screen 4, the aperture structure 5, and the optical lens 3 are each located in line with the central axis of the barrel-shaped container 1.

In this embodiment, the optical lens 3 is a convex lens, and at least one surface of the convex lens is a curved surface projecting outward (i.e., a convex surface). For example, the convex lens has two convex surfaces opposite to each other; alternatively, one surface of the convex lens is a convex surface, and the other surface may be a flat surface or a concave surface.

In this embodiment, the electronic display screen 4 is a silicon-based organic light emitting display screen, and the silicon-based organic light emitting display screen is a silicon-based micro-display screen (Si based Microdisplay) adopting an organic light emitting display technology. Among differentiators against the conventional OLED display component using amorphous silicon, microcrystalline silicon or low-temperature polysilicon thin-film transistor as a backboard, the Si based Microdisplay is an active OLED display component made by taking single crystal silicon as an active driving backboard, and has a pixel size of about 1/10 of the conventional display component, a fineness much higher than that of the conventional display component, and has many advantages such as high resolution, high integration, low power consumption, small volume, light weight. In other embodiments, the electronic display screen 4 may be another type of micro display screen, which is not limited by the present disclosure, as long as the displayed optical image can meet the requirements.

Still referring to FIG. 1, the display device 10 further includes a sealant 6 configured at a lower edge of the optical lens 3. The sealant 6 is configured to fix the position of the optical lens 3 and seal the aperture structure 5 and the liquid 2 in the barrel-shaped container 1.

If the temperature of the display device 10 changes drastically during use, it may cause voids to be left inside the barrel-shaped container 1, thereby causing air bubbles. The air bubbles may cause refraction and reflection of the lights emitted from the electronic display screen 4, which adversely affects the display effect. For this reason, the materials of the barrel-shaped container 1 and the aperture structure 5 should be properly selected to minimize the difference in thermal expansion coefficient between the barrel-shaped container 1 and the aperture structure 5.

In one embodiment, the barrel-shaped container 1 and the aperture structure 5 are made of the same metal material. In such way, not only the difference in the thermal expansion coefficient between the barrel-shaped container 1 and the aperture structure 5 may be reduced, and the generation of air bubbles can be avoided, but also the phenomenon of electrolysis of different metals in a liquid having a certain conductivity and the electrochemical corrosion caused thereby may be prevented.

Accordingly, manufacturing methods of a display device are further provided according to the present disclosure. Referring to FIGS. 1, 4 to 6, one of the manufacturing methods of the display device (that is, manufacturing method 1) includes the following steps.

In a step 1, a barrel-shaped container 1 with an overflow hole 1a is provided, and an electronic display screen 4 is mounted at a bottom of the barrel-shaped container 1.

In a step 2, a funnel-shaped aperture structure 5 is tightly fitted into the cavity of the barrel-shaped container 1.

In a step 3, a transparent and thermally conductive liquid 2 is injected into the barrel-shaped container 1.

In a step 4, an optical lens 3 is mounted on the aperture structure 5 and an optical axis of the optical lens 3 is kept perpendicular to a light emitting area of the electronic display screen 4, and excess liquid and air is discharged through an overflow hole 1a of the barrel-shaped container 1.

In a step 5, a gap between the optical lens 3 and the barrel-shaped container 1 is sealed with a sealant 6, and the overflow hole 1a is sealed with the sealant 6.

Specifically, first, a barrel-shaped container 1 with an overflow hole is provided, and an electronic display screen 4 is mounted at the bottom of the barrel-shaped container 1.

In this embodiment, a mounting hole is provided in the bottom of the barrel-shaped container 1, and the electronic display screen 4 is mounted in the mounting hole. In order to ensure the air tightness of the barrel-shaped container 1, the gap between the barrel-shaped container 1 and the electronic display screen 4 is sealed by a sealant. The sealant after being cured may prevent liquid leakage and air entering. Therefore, the process of mounting an electronic display screen 4 at the bottom of the barrel-shaped container 1 includes: first, fitting the electronic display screen 4 into the hole in the bottom of the barrel-shaped container 1 and configuring the surface of the transparent protection layer 42 of the electronic display screen 4 to be flush with or higher than the inner surface of bottom of the barrel-shaped container 1; using a sealant to seal the gap between the electronic display screen 4 and the barrel-shaped container 1; and then, curing the sealant.

In other embodiments, the bottom of the barrel-shaped container 1 may not be provided with the mounting hole, and the electronic display screen 4 is directly mounted on the inner surface of the bottom of the barrel-shaped container 1. However, in this case, a wire through hole is required to be provided in the barrel-shaped container 1, and the signal wires and control wires of the electronic display screen 4 are led out through the wire through hole.

In this embodiment, at least one overflow hole 1a is provided at the sidewall of the barrel-shaped container 1, and the overflow hole 1a is configured to discharge air or part of the liquid that overflows during assembling of the display device 10.

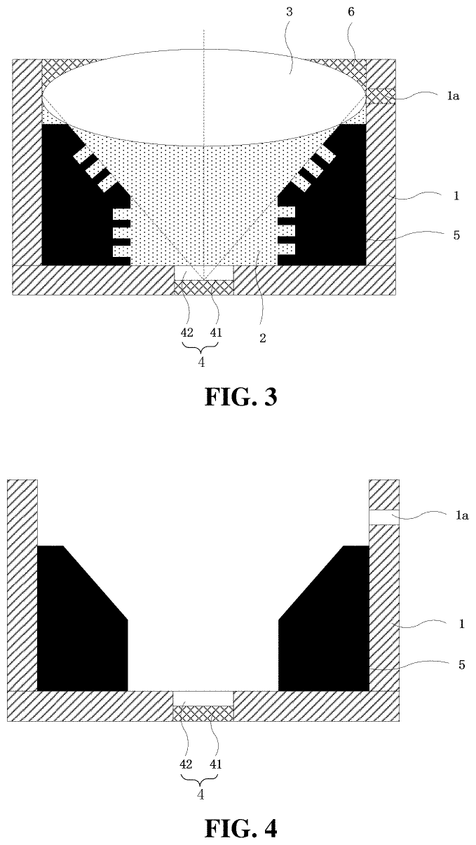

Next, as shown in FIG. 4, an aperture structure 5 is provided, and the aperture structure 5 is fitted into the cavity of the barrel-shaped container 1 so that a bottom end of the aperture structure 5 abuts on the inner surface of the bottom of the barrel-shaped container 1, and an outer sidewall of the aperture structure 5 is in close contact with the inner sidewall of the barrel-shaped container 1.

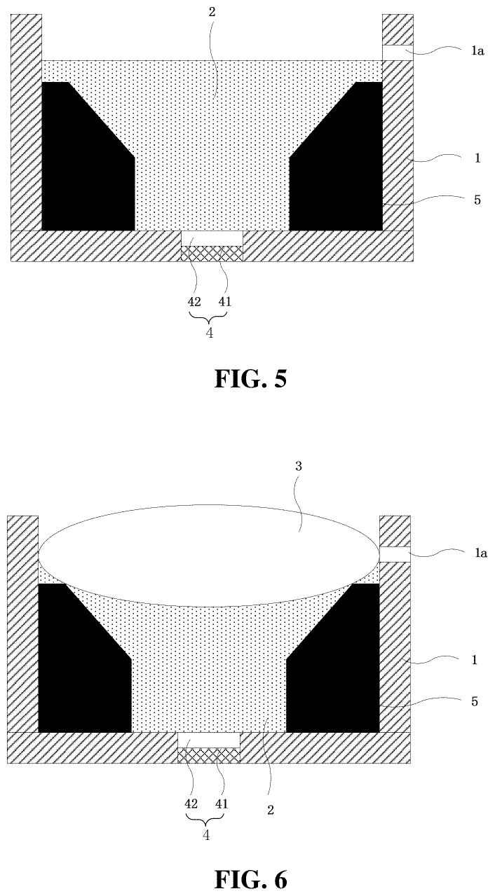

Then, as shown in FIG. 5, the liquid 2 after being defoamed is injected into the barrel-shaped container 1 through the opening of the barrel-shaped container 1 until the liquid 2 reaches the level of the overflow hole la. When the liquid 2 flows out of the overflow hole 1a provided in the barrel-shaped container 1, the injecting of liquid 2 is stopped.

Then, as shown in FIG. 6, an optical lens 3 is horizontally placed on the aperture structure 5 by a robot arm (not shown) with a vacuum chuck, and the optical lens 3 is in contact with a top end of the aperture structure 5. During placement, an optical axis of the optical lens 3 should be configured perpendicular to a light emitting area of the electronic display screen 4, and moreover, excess liquid 2 and bubbles that may remain in the liquid 2 are discharged by the overflow hole 1a. In order to ensure that the excess liquid 2 may be smoothly discharged from the overflow hole 1a, the size of the opening of the barrel-shaped container 1 is required to be larger than the diameter of the optical lens 3 in a long axis direction.

Finally, as shown in FIG. 1, a sealant 6 is applied to the peripheral position of the optical lens 3 to seal the gap between the optical lens 3 and the barrel-shaped container 1 and to seal the overflow hole 1a, and then the sealant 6 is subjected to curing treatment so that an upper edge of the optical lens 3 is bonded to a housing of the barrel-shaped container 1. Thus, the display device 10 is formed.

It is to be noted that all of the above manufacturing processes may be performed in an environment with air or in an enclosed space having a certain degree of vacuum. In a case where the display component is manufactured in a vacuum environment, air may be further prevented from being trapped inside the barrel-shaped container 1 and the liquid 2, and air may be prevented from precipitating from the inner wall of the container or the liquid and turning into bubbles, thus, no bubbles may be generated even when the temperature changes or the orientation of the container changes, such as in inversion or vibration.

It is to be noted that in the packaging process from the step 3 to the step 5, the barrel-shaped container 1 and the liquid 2 should be kept in a constant temperature state, and the temperature in the packaging process is required to be between 36 degrees Celsius and 60 degrees Celsius. In this way, as long as the operating temperature of the display device 10 is lower or slightly higher than this packaging temperature, generally no air bubbles will be presented in the barrel-shaped container 1.

### Second Embodiment

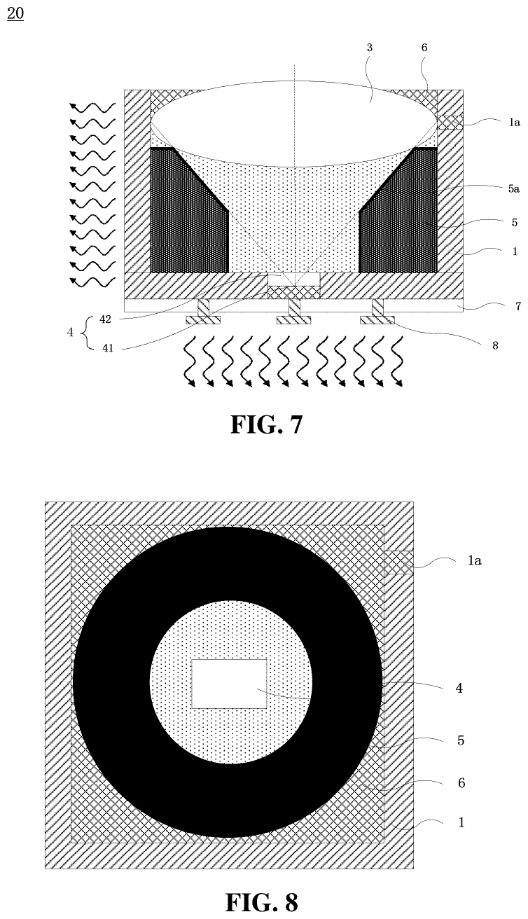

Referring to FIGS. 7 and 8, which are structural diagrams of a display device according to a second embodiment of the present disclosure. As shown in FIGS. 7 and 8, the display device 20 includes: a barrel-shaped container 1 filled with a liquid 2, an optical lens 3, and an electronic display screen 4. The liquid 2 is a transparent and thermally conductive liquid and mixed with a dispersant and nanoparticles. The optical lens 3 is mounted at one end of the barrel-shaped container 1, and one surface of the optical lens 3 is in contact with the liquid 2. The electronic display screen 4 includes a light emitting area 41 and a transparent protection layer 42. Specifically, the electronic display screen 4 is mounted at the other end of the barrel-shaped container 1, and the transparent protection layer 42 of the electronic display screen 4 is in contact with the liquid 2. The optical lens 3 has an optical axis that perpendicularly passes through the center of the light emitting area 41.

Specifically, this embodiment differs from the first embodiment in that the barrel-shaped container 1 is not a circular barrel-shaped container, but a rectangular barrel-shaped container. The rectangular barrel-shaped container includes a rectangular bottom plate and four rectangular side plates arranged to surround the outer periphery of the rectangular bottom plate, the four side plates are sequentially connected end to end and arranged perpendicular to the rectangular bottom plate, and the four rectangular side plates are integrally formed with the rectangular bottom plate. Compared with the circular barrel-shaped container, the rectangular barrel has a larger margin for drum deformation caused by cold shrinkage than that provided by the circular barrel when the use temperature is lower than the packaging temperature.

In one embodiment, the rectangular bottom plate has a thickness larger than the thickness of the rectangular side plates. That is, the thickness of the sidewalls of the barrel-shaped container is smaller than the thickness of the bottom housing thereof. Thus, when the temperature changes, the barrel-shaped container 1 is deformed mainly in sidewalls, and not in the bottom thereof, thereby ensuring that the electronic display screen 4 adjacent to the bottom of the container is not adversely affected accordingly.

Still referring to FIG. 7, a light absorbing layer 5a is configured on each of light incident surfaces of the aperture structure 5 for reducing light reflection. Since the aperture structure 5 does not completely cover the inner surface of the barrel-shaped container 1, the light absorbing layer (not shown in the figures) is also configured on the inner surface of the barrel-shaped container 1 in order to prevent the reflection of lights on the inner surface of the barrel-shaped container 1 from causing a ghost problem to the output optical image. The light absorbing layer configured on the surfaces of the aperture structure 5 and the barrel-shaped container 1 is a black plating layer, or a thin layer of low reflection film formed on the metal surface by using methods such as anodizing. Still referring to FIG. 7, the display device further includes a PCB 7 and multiple metal connectors 8. The PCB 7 is attached to an outer side surface of the barrel-shaped container 1 and electrically connected to the electronic display screen 4. The metal connectors 8 are in a nail shape or a screw shape, and the PCB 7 is fixed to the barrel-shaped container 1 through the metal connectors 8, and areas dissipating heat outwards as indicated by arrows are mainly the sidewalls and the bottom of the barrel-shaped container 1.

In this embodiment, the heat generated by the electronic display screen 4 may be rapidly conducted to the barrel-shaped container 1 and the aperture structure 5 through the liquid 2 and finally dissipated to the external environment, but also. In addition, the heat generated by the electronic display screen 4 may be dissipated through the PCB 7 and the metal connectors 8 supplementally, so that the efficiency of heat conduction is further improved.

In one embodiment, the barrel-shaped container 1, the PCB 7, and the metal connectors 8 are all connected to a constant potential, such as a ground potential, to shield ambient electromagnetic interference, thereby ensuring normal display of the electronic display screen 4.

In the display device according to the present disclosure, the optical lens 3 and the electronic display screen 4 are packaged in the barrel-shaped container 1 to form an integrated structure, and the liquid 2 is injected in the integrated structure. The liquid 2 cooperates with the barrel-shaped container 1 to rapidly discharge heat generated by the electronic display screen 4, thereby improving the service life and the use safety of the display device. The integrated structure may also be combined with other optical components to form AR glasses, VR glasses, or other intelligent wearable apparatuses. The inventors found that heat generation is most concentrated in the high-speed digital image processing chip and OLEDs having high-resolution and high-brightness in the entire system of AR glasses or VR glasses. Those components together with their surrounding components and packaging housing will all heat up rapidly after the system runs shortly. When the display device provided by the present disclosure is applied to the AR glasses or the VR glasses, the heat dissipation issues of these intelligent wearable apparatuses may be effectively addressed.

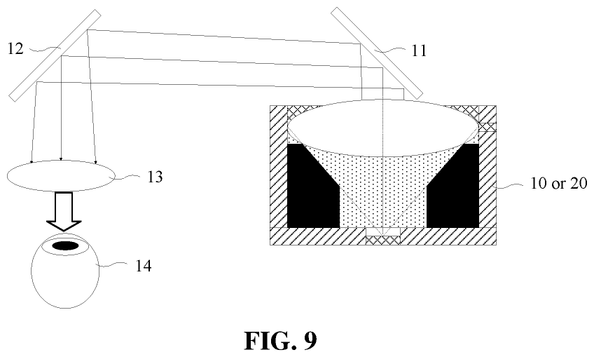

Referring to FIG. 9, which is a structural diagram of AR glasses according to an embodiment of the present disclosure. As shown in FIG. 9, the AR glasses include a display device 10 (or a display device 20), a lens barrel (not shown in the figure), a first mirror 11, a second mirror 12, and another optical lens 13. The first mirror 11, the second mirror 12, the optical lens 13 and the optical lens 3 in the display device constitute an optical system, and an optical image displayed on the electronic display screen 4 is enlarged by the optical system and transferred to a human eye.

The optical image displayed on the electronic display screen 4 generally includes lights of three basic colors: red (R), green (G), and blue (B). The lights after passing through the optical lens 3 become almost parallel lights, and those parallel lights are then reflected by the first mirror 11 into transversely propagating light beams. These transversely propagating light beams travel within the lens barrel for a certain distance and then reach the second mirror 12 and are reflected by the second mirror 12 into longitudinally propagating light beams. These longitudinally propagating light beams enter the human eye directly or are focused by the optical lens 13 and then reach the human eye 14.

In this embodiment, the optical lens 3 functions as an objective lens, and the other optical lens 13 functions as an eyepiece lens. The objective lens is a convex lens, and the eyepiece lens is a concave lens.

The above figures simply schematically show the display device according to the present disclosure. For the sake of clarity, the shapes and the numbers of the elements in the above figures are simplified, and some elements are omitted, variations may be made by a person skilled in the art according to practical requirements, and these variations are all within the protection scope of the present disclosure, and are not described herein again.

It is to be noted that the various embodiments in this specification are described in a progressive manner. Each of the embodiments is mainly focused on describing its differences from other embodiments, and references may be made among these embodiments with respect to the same or similar portions among these embodiments. The manufacturing method of the display device 20 is similar to that of the display device 10, and details are not described herein.

In summary, according to the display device and the manufacturing method thereof provided by the present disclosure, the optical lens and the electronic display screen are provided in the barrel-shaped container to form an integrated structure, and the thermally conductive liquid is injected into the integrated structure to realize rapid heat dissipation, thereby improving the service life and the use safety of the display device. The display device not only is compact in structure, but also may timely discharge heat generated by the electronic display screen, and is therefore more suitable for intelligent wearable apparatuses.

The above is a further detailed description of the present disclosure with reference to the preferred embodiment/implementation, and it is not assumed that the specific implementation of the present disclosure is limited to these descriptions. For a person of ordinary skill in the art to which the present disclosure pertains, a number of simple deductions or substitutions may be made without departing from the concept of the present disclosure, all of the deductions or substitutions should be deemed as falling within the protection scope of the present disclosure.

What is claimed is:

1. A display device comprising:
a barrel-shaped container filled with a liquid, wherein the liquid is transparent and thermally conductive and mixed with a dispersant and nanoparticles;
an optical lens mounted at one end of the barrel-shaped container that one surface of the optical lens is in contact with the liquid; and
an electronic display screen mounted at the other end of the barrel-shaped container, wherein the electronic display screen comprises a light emitting area covered by a transparent protection layer that the transparent protection layer is in contact with the liquid; and
the optical lens comprises an optical axis that perpendicularly passes through a center of the light emitting area.

2. The display device of claim 1, wherein the liquid further comprises: a mixed solution with deionized water and ethylene glycol, or a silicone oil.

3. The display device of claim 1, wherein each of the nanoparticles is less than 100 nanometer (nm) in any dimension.

4. The display device of claim 3, wherein the nanoparticles comprise nanorods that a ratio between an average diameter of the nanorods and an average length of the nanorods is less than 0.75.

5. The display device of claim 3, wherein the nanoparticles are made of a metal or a metal oxide, the metal is selected from gold, silver, copper or aluminum, and the metal oxide is selected from titanium dioxide, aluminum oxide or copper oxide.

6. The display device of claim 1, further comprising an aperture structure that is disposed in the liquid and between the optical lens and the electronic display screen, in a manner that the optical axis of the optical lens passes through a center of the aperture structure.

7. The display device of claim 6, wherein the aperture structure comprises a conic-shaped funnel structure with its larger exit being close to the optical lens and its smaller exit being close to the electronic display screen.

8. The display device of claim 7, wherein the aperture structure is made of a metal material, covered by a light absorbing layer on a light incident surface of the aperture structure for reducing light reflection.

9. The display device of claim 7, wherein an inner sidewall of the funnel structure comprises a wetting surface on which there are a plurality of grooves or dimples arranged periodically or randomly such that the wetting surface has a surface roughness greater than 1.25.

10. The display device of claim 1, wherein at least one overflow hole is configured at the sidewall of the barrel-shaped container to discharge air or part of the liquid that overflows during assembling.

11. The display device of claim 10, wherein at least one injection hole is configured on the barrel-shaped container to inject the liquid.

12. A manufacturing method of a display device, comprising:
a step 1: providing a barrel-shaped container with an overflow hole, and mounting an electronic display screen at a bottom of the barrel-shaped container;
a step 2: tightly fitting a funnel-shaped aperture structure into the cavity of the barrel-shaped container;
a step 3: injecting a transparent and thermally conductive liquid into the barrel-shaped container;
a step 4: mounting an optical lens on the aperture structure while keeping an optical axis of the optical lens perpendicular to a light emitting area of the electronic display screen, and discharging excess liquid and air through an overflow hole of the barrel-shaped container;
a step 5: sealing a gap between the optical lens and the barrel-shaped container with a sealant, and sealing the overflow hole with the sealant;
in the manufacture process from the step 3 to the step 5, maintaining the temperature of the barrel-shaped container and the liquid to be within a range from 36 degrees Celsius (° C.) to 60° C.
